(19) United States
(12) Patent Application Publication
(10) Pub. No.: US 2022/0165669 A1
(43) Pub. Date: May 26, 2022

(54) SEMICONDUCTOR DEVICE STRUCTURE, STACKED SEMICONDUCTOR DEVICE STRUCTURE AND METHOD OF MANUFACTURING SEMICONDUCTOR DEVICE STRUCTURE

(71) Applicant: Taiwan Semiconductor Manufacturing Company, Ltd., Hsinchu (TW)

(72) Inventors: Chen-Hua Yu, Hsinchu City (TW); Kuo-Chung Yee, Taoyuan City (TW)

(73) Assignee: Taiwan Semiconductor Manufacturing Company, Ltd., Hsinchu (TW)

(21) Appl. No.: 17/105,341

(22) Filed: Nov. 25, 2020

(51) Int. Cl. H01L 23/528; H01L 25/065; H01L 23/00; H01L 23/48; H01L 21/768; H01L 25/00

(52) U.S. Cl. CPC H01L 23/5286; H01L 25/0657; H01L 24/08; H01L 23/481; H01L 21/76898; H01L 2224/80896; H01L 25/50; H01L 2225/06541; H01L 2224/08145; H01L 2224/80895; H01L 24/80

(57) ABSTRACT

An integrated circuit structure includes a front end of line structure, a front side back end of line structure, and a backside back end of line structure. The front end of line structure includes a device and a power/ground contact connecting the device. The front side back end of line structure disposed over a front side of the front end of line structure. The backside back end of line structure is disposed over a backside of the FEOL structure and includes a power/ground interconnect connecting the power/ground contact.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is integrated fan-out (InFO) technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 5 illustrate cross sectional views of an intermediate stage in a manufacturing of an integrated circuit structure according to some exemplary embodiments of the present disclosure.

FIG. 6 illustrates a cross sectional view of an integrated circuit structure according to some exemplary embodiments of the present disclosure.

FIG. 7 illustrates a cross sectional view of an integrated circuit structure according to some exemplary embodiments of the present disclosure.

FIG. 8 illustrates a cross sectional view of an integrated circuit structure according to some exemplary embodiments of the present disclosure.

FIG. 9 to FIG. 12 illustrate cross sectional views of an intermediate stage in a manufacturing of an integrated circuit structure according to some exemplary embodiments of the present disclosure.

FIG. 13 illustrates a cross sectional view of an integrated circuit structure according to some exemplary embodiments of the present disclosure.

FIG. 14 illustrates a cross sectional view of an integrated circuit structure according to some exemplary embodiments of the present disclosure.

FIG. 15 illustrates a cross sectional view of an integrated circuit structure according to some exemplary embodiments of the present disclosure.

FIG. 16 to FIG. 22 illustrate cross sectional views of an intermediate stage in a manufacturing of a stacked integrated circuit structure according to some exemplary embodiments of the present disclosure.

FIG. 23 illustrates a cross sectional view of a stacked integrated circuit structure according to some exemplary embodiments of the present disclosure.

FIG. 24 illustrates a cross sectional view of a stacked integrated circuit structure according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” “third,” “fourth,” and the like, may be used herein for ease of description to describe similar or different element(s) or feature(s) as illustrated in the figures, and may be used interchangeably depending on the order of the presence or the contexts of the description.

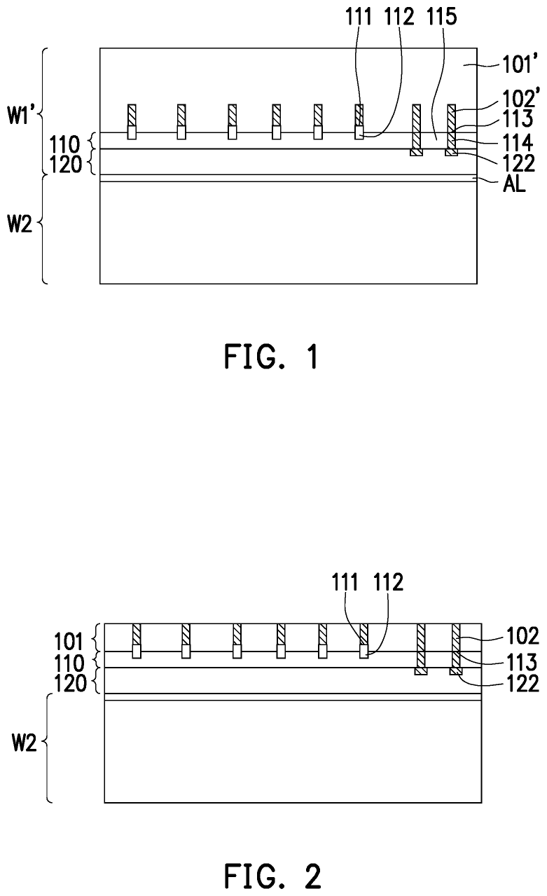

FIG. 1 to FIG. 5 illustrate cross sectional views of an intermediate stage in a manufacturing of an integrated circuit structure according to some exemplary embodiments of the present disclosure. In accordance with some embodiments of the disclosure, an integrated circuit is transformed into an integrated circuit structure with back side power distribution network (PDN) based on creation of a wiring scheme that is disposed on both sides of the device layer (front end of line structure). Referring to FIG. 1 and FIG. 2, a semiconductor wafer W1′ is provided on a carrier W2. In some embodiments, the semiconductor wafer W1′ may include a base substrate 101′, a front end of line (FEOL) structure 110 disposed on the base substrate 101′, a front side back end of line (BEOL) structure 120 disposed over a front side of the FEOL structure 110. Herein, “front side” is referred to the side of the FEOL structure 110 that faces away from the base substrate, while “backside” is referred to the side that is opposite to the front side and faces the base substrate. In some embodiments, the carrier W2 may be a carrier substrate, an integrated circuit, or an interposer. In the present embodiment, the carrier W2 is a carrier substrate, but the disclosure is not limited thereto. The semiconductor wafer W1′ is disposed on the carrier W2 with a bonding surface of the front side back end of line structure 120 bonded to the carrier W2 through an adhesive layer AL. The adhesive layer may be a high thermal conductive bonding layer and/or hybrid bonding layer, which may include diamond-like carbon (DLC) coating, silicon carbide coating, Cu-SiOx coating, SiON coating, or the like.

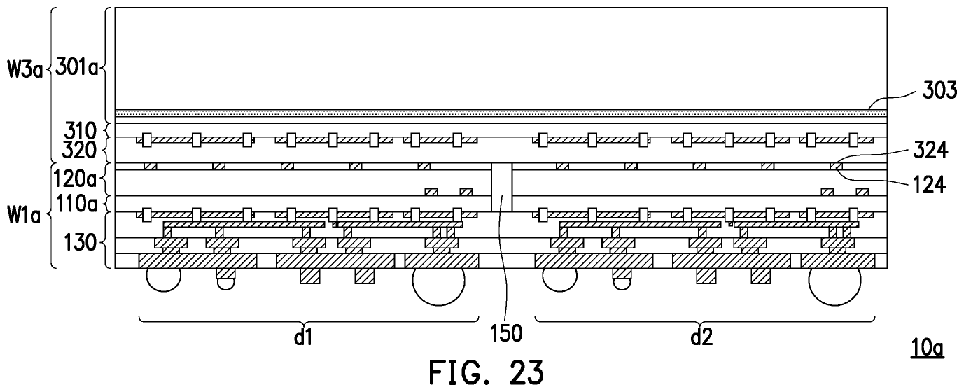

In some embodiments, the FEOL structure 110 (shown in an abstract form as a layer for convenience of illustration) may include a device 112 (a plurality of devices 112 are illustrated herein but not limited thereto) and a power/ground and/or I/O contact 111 (a plurality of power/ground contacts 111 are illustrated herein but not limited thereto) connecting the device 112. In some exemplary embodiments, a FEOL structure 110 is formed at a base substrate 101′ and interconnected on top and bottom using the front side back end of line structure 120 and a backside BEOL structure (which will be formed subsequently) respectively. In some embodiments, the base substrate 101′ may be in a wafer form. In at least one embodiment, the base substrate 101′ may comprise silicon (Si). In some embodiments, the base substrate 101′ may include a semiconductor element, such as germanium (Ge), or a compound semiconductor, such as silicon carbide (SiC), gallium arsenide (GaAs), indium arsenide (InAs), or indium phosphide (InP). In at least one embodiment, the base substrate 101′ may have a silicon on insulator (SOI) structure. For example, the base substrate 101′ may include a buried oxide (BOX) layer (such as a buried oxide (BOX) layer 303 shown in FIG. 23). In some embodiments, the base substrate 101′ may have a conductive region, for example, an impurity-doped well, or an impurity-doped structure. In addition, the base substrate 101′ may have various isolation structures, such as a shallow trench isolation (STI) structure. It is noted that, in additional to I/O contacts 113, the contacts 111 may include both Power/Ground and I/O function.

In some embodiments, the FEOL structure 110 may include a plurality of devices and an interlayer insulating layer 115. The devices 112 may include various microelectronic devices, for example, a FinFET, a metal-oxide-semiconductor field (MOSFET) effect transistor, a large scale integration (LSI) system, an image sensor, such as a complementary metal-oxide-semiconductor (CMOS) imaging sensor (CIS), a micro-electro-mechanical system (MEMS), an active device, or a passive device. Some of the devices 112 are formed in the base substrate 101′ and some of which are formed upon the top surface of the base substrate 101′. The devices 112 may be electrically connected to a conductive region of the base substrate 101′. In addition, the devices 112 may each be electrically separated from their neighboring individual devices by the interlayer insulating film. In one of the embodiments, the FEOL structure 110 may include a plurality of semiconductor device layers stacked monolithically. In some embodiments, the FEOL structure 110 especially for high performance applications may be built on a silicon-on-insulator (SOI) or other similar substrate in which an embedded layer (such as a buried oxide (BOX) layer 103 shown in FIG. 23) may be implemented under the FEOL structure 110 (e.g., device region). In some embodiments, the FEOL structure 110 may include various transistors (e.g. devices 112) and the associated contact regions, e.g. power/ground and/or I/O contacts 111, input/output (I/O) contacts 113, etc., required for such devices. In some embodiments, an interconnect via 114 configured to connect the device contacts (e.g., I/O contacts 113) to the front side BEOL structure 120 and surrounded by the interlayer insulating layer 115 is also presented in the FEOL structure 110.

In accordance with some embodiments of the disclosure, the FEOL structure 110 may include a plurality of power/ground and/or I/O contacts 111 and a plurality of I/O contacts 113. In the present embodiment, at least one interconnect via 113 (a plurality of interconnect vias 114 are illustrated but not limited thereto) is configured for electrically connecting the I/O contacts 113 on the device 112 and at least one I/O interconnect 122 (a plurality of I/O interconnect 122 are illustrated but not limited thereto) of the front side BEOL structure 120. That is to say, the I/O contacts 112 is electrically extended to an opposite surface of the FEOL structure 110 through the interconnect vias 114 for connecting with the I/O interconnects 122 of the front side BEOL structure 120. However, the present embodiment is merely for illustration. Interconnecting manner of the I/O contacts 113 are not limited in the disclosure.

In some embodiments, the front side BEOL structure 120 (also shown in an abstract form as a layer for convenience of illustration) is formed over the FEOL structure 110. The front side BEOL structure 120 may include layers of metallic wiring (interconnects) surrounded by insulating dielectrics, which are preferably low in dielectric constant (low k), stacked monolithically. The interconnects contains metallic structures, typically composed of copper, that provide external interconnections (interconnects) which are formed in many levels of Intra-Level Dielectric (ILD) layers (i.e. an ILD stack) for electrically connecting the numerous active devices on the base substrate 101′ to external devices. In some embodiments, the front side BEOL structure 120 may include at least one I/O interconnect 122 (electrically) connected to the interconnect vias 114, so that the I/O interconnects 122 of the front side BEOL structure 120 are connected to the I/O contacts 112 of the FEOL structure 110.

Referring to both FIG. 1 and FIG. 2, in some embodiments of the disclosure, the base substrate 101 may include at least one through substrate via 102 (a plurality of through substrate vias 102 are illustrated but not limited thereto) extending through the base substrate 202 (not shown). The through substrate vias 102 are configured for connecting the power/ground contact 111 and the backside BEOL structure formed subsequently. In one or more embodiments, the process of forming through substrate via 102 may start with a blind via 102′ as it is shown in FIG. 1, and eventually exposed such that the metal is substantially coplanar with the back surface of the base substrate 101 as it is shown in FIG. 2. For example, at least one blind via 102′ is provided on the base substrate 101′, and the blind via 102 is (electrically) connected to the power/ground contact 111.

In some instances, the blind vias 102′ might only be “blind” with respect to the back surface. By way of further clarification, the blind vias 102′ are technically blind whenever they cannot be accessed from above and below. On the original semiconductor wafer W1′, they are blind because they can be accessed from the contacts (e.g. power/ground contacts 111), but not bottom. When the carrier W2 is attached, technically they are blind or buried from both sides. When exposed as in the example herein, they are actually still blind due to the carrier W2, but from the point of view of the original semiconductor wafer W1′ they are through vias after exposure.

In some embodiments, a thinning process is performed on a backside of the base substrate 101′ till an end of the blind via 102′ is exposed, so as to form the through substrate vias 102 shown in FIG. 2. In some embodiments, the thinning process includes a grinding process. In some other embodiments, the thinning process includes a chemical-mechanical polishing (CMP) process or the like. For example, the structure shown in FIG. 1 may be provided on a wafer grinding tool. Mechanical thinning may include, for example, the following three steps: coarse grinding, fine grinding, and final polish. The grinding is carried out on the backside of the base substrate 101′. Coarse grinding is used to remove the bulk of the wafer, but the coarse grind process, although quite fast, leaves a very rough surface. It is thus preferred to stop the coarse grind process before reaching the final target, and to then switch to the fine grind wheel. Once the final target is reached, a final silicon polish should be used to create a mirror finish. The final polish may be or similar to a standard silicon chemical-mechanical polishing (CMP) process. If the final polish is not done, wet etching using tetramethylammonium hydroxide (TMAH) or potassium hydroxide (KOH) will quickly reveal “swirl patterns” caused by the fine grind wheel. A final polish will leave the silicon surface pristine and ready for further thinning. It is also preferred to use a proper brush cleaning or wet clean process, which may include wiping with isopropyl alcohol (IPA) followed by a water rinse and spin dry, to remove any trace of polish slurry which might act as an etch mask during the via exposure steps. In one or more embodiments, a blanket deep reactive ion etching (D-RIE) or a Si reactive ion etching (RIE) process may be performed to exposed the through substrate vias 102. The method of thinning the base substrate 101′ and exposing the through substrate vias 102 is not limited thereto.

With now reference to FIG. 3, in accordance with some embodiments of the disclosure, a BEOL process is performed over the base substrate 101, so an ensemble of a backside BEOL structure 130 are built up on top of the base substrate 101. In the back end of line processing steps, interconnects containing multiple layers of wirings 132 and dielectric passivation layers are built over a backside of the FEOL structure 110 that contains the devices 112. The backside BEOL structure 130 includes vias 134 and wirings 132 are fabricated atop the base substrate 101 as illustrated in FIG. 3. In some embodiments, the backside BEOL structure 130 may include at least one power/ground interconnect(s) 1321 connecting the power/ground and/or I/O contacts 111. As stated above, the wirings 132 (metallic structures) including the power/ground interconnect(s) 1321 for providing external interconnections (interconnects) are formed in many levels of Intra-Level Dielectric (ILD) layers for electrically connecting some of the power/ground contacts 111 on the FEOL structure 110 to external devices. That is to say, the layers of the backside BEOL structure 130 provide functions such as power and ground network (PDN) required for operating the circuitry in the integrated circuit structure 100 (not shown). In some embodiment, at least one passive device 136 may be integrated with metal and other materials in the backside BEOL structure 130. In some embodiments, the passive device 136 may include integrated passive dies (IPD), digitally tunable capacitors (DTC), metal-insulator-metal (MiM) decoupling capacitors, or the like.

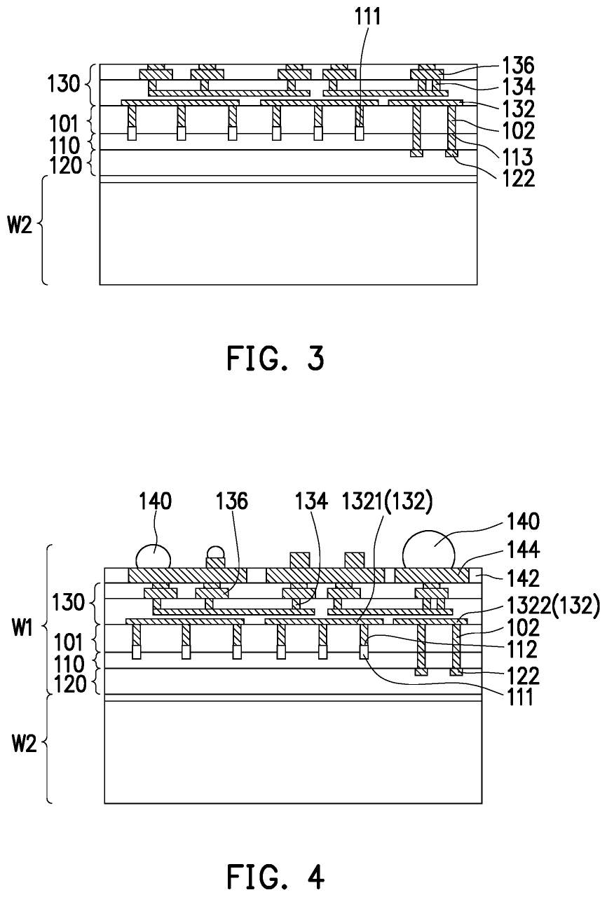

With now reference to FIG. 4, at least one conductive bump(s) 140 is provided over a bonding surface of the backside BEOL structure 130. In some embodiments, the conductive bumps 140 are connected to the power/ground interconnects 1321 and may serve as power/ground terminals of the integrated circuit structure 100. For example, a passivation layer 142 is applied atop the backside BEOL structure 130 and contact holes are opened and filled with a bonding metallurgy and the conductive bumps 140 are disposed onto selected locations on the bonding pads 144 as shown in FIG. 4. Accordingly, the conductive bumps 140 serve as the power/ground terminals of the integrated circuit structure 100. Throughout the description, the resultant structure overlaying on the carrier W2 is referred to as an integrated circuit wafer W1.

In the present embodiment, the backside BEOL structure 130 may further include I/O interconnects 1322 for connecting the I/O contacts 113 of the FEOL structure 110. At least one of the conductive bumps 140 may be connected to the I/O interconnects 1322 and serve as the I/O terminal of the integrated circuit structure 100. However, the disclosure does not limit the arrangements of the I/O interconnects and I/O terminals.

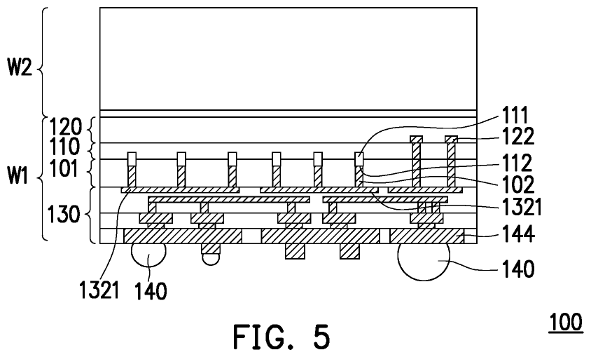

Referring to FIG. 5, then, upon completion of the process described above, the resultant structure shown in FIG. 4, which is in a wafer form, is ready to be divided into individual integrated circuit structures 100 by dicing through a plurality of scribing (dicing) lines to provide separation into individual integrated circuit structures 100. The integrated circuit structure 100 shown in FIG. 5 may be flip chip joined to a suitable packaging carrier (not shown) for use in product applications.

With such process and configuration, the front side BEOL structure 120 and the backside BEOL structure 130 are disposed on two opposite sides (i.e., front side and backside) of the FEOL structure 110. The base substrate 101 is disposed between the FEOL structure 110 and the backside BEOL structure 130, and the through substrate vias 102 extend through the base substrate 101 and connect the power/ground and/or I/O contacts 111. Accordingly, the power/ground contacts 111 of the FEOL structure 110 are connected to the power/ground interconnects 1321 of the backside BEOL structure 130 through the through substrate vias 102 of the base substrate 101. That is to say, the through substrate vias 102 directly contact the power/ground contacts 111 of the device 112 to extend the power and ground network to the backside of the integrated circuit structure 100. Thereby, electrical paths of power and ground networks are shorten and the electrical performance of the integrated circuit structure 100 can be improved. Moreover, since the power/ground interconnects 1321 are arranged on the backside of the FEOL structure 110, the front side BEOL structure 120 (on the front side of the FEOL structure 110) is free of power/ground interconnects that are configured to connect the power/ground contact 111. Therefore, the power/ground interconnects would not be interfered with the I/O interconnects 122 in the front side BEOL structure 120, and parasitic capacitance of the integrated circuit structure 100 can be reduced.

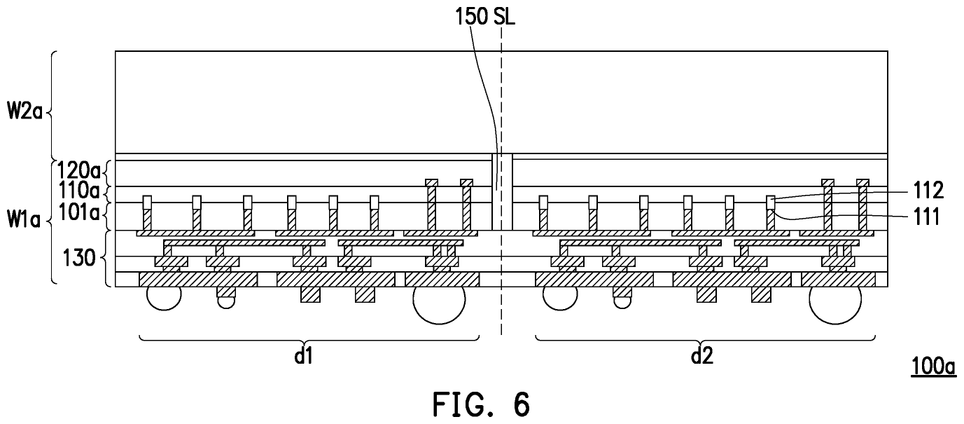

FIG. 6 illustrates a cross sectional view of an integrated circuit structure according to some exemplary embodiments of the present disclosure. It is noted that the integrated circuit structure 100a shown in FIG. 6 contains many features same as or similar to the integrated circuit structure 100 disclosed earlier with FIG. 1 to FIG. 5. For purpose of clarity and simplicity, detail description of same or similar features may be omitted, and the same or similar reference numbers denote the same or like components. The main differences between the integrated circuit structure 100a shown in FIG. 6 and the integrated circuit structure 100 disclosed earlier with FIG. 5 are described as follows.

With now reference to FIG. 6, in the present embodiment, the integrated circuit wafer W1a is a reconstructed wafer. That is, instead of providing the integral semiconductor wafer W1′ including the base substrate 101′, the FEOL structure 110 and the front side BEOL structure 120 shown in FIG. 5, a plurality of semiconductor dies d1, d2 are firstly provided on the carrier W2. That is to say, the process in the embodiment shown in FIG. 1 to FIG. 5 is a wafer to wafer process while the process in the present embodiment is a die to wafer process. It is noted that two semiconductor dies d1 and d2 are shown in FIG. 6 merely for illustration purpose. More or less semiconductor dies may be provided on the carrier W2. In the present embodiment, the carrier W2 may be an interposer, but the disclosure is not limited thereto. Each of the semiconductor dies d1/d2 includes a base substrate 101a, a FEOL structure 110a and a front side BEOL structure 120a. The layouts and the fabricating processes of the base substrate 101a, the FEOL structure 110a and the front side BEOL structure 120a are similar to those of the base substrate 101, the FEOL structure 110 and the front side BEOL structure 120 described earlier, so detail description of same or similar features may be omitted. Such semiconductor dies d1, d2 are joined together by, for example, a dielectric coating to form the reconstructed wafer W1a. Then, the sequential processes can be performed on the reconstructed wafer W1a to form the integrated circuit structure 100a. In the resultant structure after dicing along the scribe line SL, a dielectric material 150 covers side surfaces of the base substrate 101a, the FEOL structure 110a, and the front side BEOL structure 120a as it is shown in FIG. 6.

With such configuration, a part from those similar advantages discussed earlier in the previous embodiment, the semiconductor dies d1, d2 are provided on the carrier W2 independently, so electrical tests, or the like, can be firstly performed on the semiconductor dies d1, d2 before they are placed on the carrier W2. For example, after the semiconductor dies d1, d2 are singulated, a die pick machine picks up and places each semiconductor die d1/d2 on a, for example, testing substrate, so that it may be subjected to an electrical test, for example, to identify the good die and bad die. After the semiconductor dies d1, d2 are subjected to and pass the electrical test, the known good dies (e.g., the semiconductor dies d1, d2) are then placed and bonded to carrier W2. Therefore, such configuration ensures that only known good dies are incorporated into integrated circuit structure 100a, so as to improve yield rates of the integrated circuit structure 100e and reduce production cost.

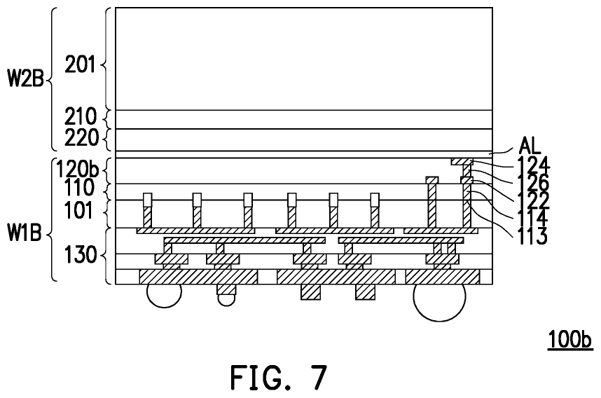

FIG. 7 illustrates a cross sectional view of an integrated circuit structure according to some exemplary embodiments of the present disclosure. It is noted that the integrated circuit structure 100b shown in FIG. 7 contains many features same as or similar to the integrated circuit structure 100 disclosed earlier with FIG. 1 to FIG. 5. For purpose of clarity and simplicity, detail description of same or similar features may be omitted, and the same or similar reference numbers denote the same or like components. The main differences between the integrated circuit structure 100b shown in FIG. 7 and the integrated circuit structure 100 disclosed earlier with FIG. 5 are described as follows.

In the present embodiment, the carrier W2b may be another integrated circuit wafer, which is a semiconductor wafer with built-in integrated circuits. In such embodiment, for the integrated circuit wafer W1b, at least one I/O terminal 124 is disposed on a bonding surface of the front side BEOL structure 120b and (electrically) connected to an I/O contact 113 on the FEOL structure 110. More or less of the I/O terminal 124 can be provided and is configured for electrically connecting the numerous active devices on the base substrate 101 to external devices (e.g. carrier W2b). In some embodiments, the I/O terminal 124 may be connected to the I/O interconnect 122 and the I/O contact 113 through interconnect vias 114, 126, or any other forms of interconnects.

Accordingly, the carrier W2b may include a base substrate 201, a FEOL structure 210 and a front side BEOL structure 220 (each of which is shown in an abstract form as a layer for convenience of illustration). In the present embodiment, the I/O terminals of the carrier W2b are disposed on a bonding surface of the carrier W2b. Therefore, when a wafer to wafer bonding (face to face bonding) process is performed, the I/O terminals 124 on the front side BEOL structure 120b of the integrated circuit wafer W1b are bonded to the I/O terminals on the front side BEOL structure 220 of the carrier W2b for signal communication. Alternatively, the I/O terminals from front side BEOL structure of the integrated circuit wafer W1b are directly bonded to I/O terminals from the front side BEOL structure of the W2b through an AL layer, which contains bonded metal pads and dielectrics. It is noted that a die to wafer bonding process may also be adapted in the present embodiment, which means the integrated circuit wafer W1b may be a reconstructed wafer including a plurality of semiconductor dies as shown in FIG. 6. The disclosure is not limited thereto.

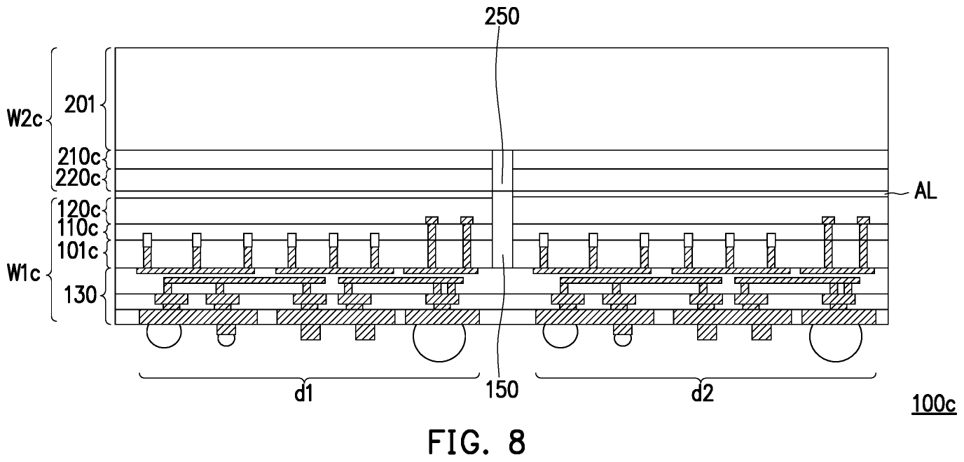

FIG. 8 illustrates a cross sectional view of an integrated circuit structure according to some exemplary embodiments of the present disclosure. It is noted that the integrated circuit structure 100c shown in FIG. 8 contains many features same as or similar to the integrated circuit structure 100b disclosed earlier with FIG. 7. For purpose of clarity and simplicity, detail description of same or similar features may be omitted, and the same or similar reference numbers denote the same or like components. The main differences between the integrated circuit structure 100c shown in FIG. 8 and the integrated circuit structure 100b disclosed earlier with FIG. 7 are described as follows.

In the present embodiment, the integrated circuit wafer W1c is a reconstructed wafer. That is, a plurality of semiconductor dies d1, d2 are provided on the carrier W2c and joined together by, for example, a dielectric material 150 to form the reconstructed wafer W1c. In the present embodiment, the carrier W2c may also be a reconstructed wafer, which includes a plurality of FEOL structures 210c separated from one another and a plurality of BEOL structures 220c separated from one another and stacked on the FEOL structures 210c respectively. Stacks of the FEOL structures 210c and the BEOL structures 220c are joined together by, for example, a dielectric material 250 to form the reconstructed wafer W2c. Each of the semiconductor dies d1/d2 includes a base substrate 101a, a FEOL structure 110a and a front side BEOL structure 120a. The layouts and the fabricating processes of the semiconductor dies d1/d2 are similar to those of the semiconductor dies d1/d2 described earlier in FIG. 6, so detail description of same or similar features may be omitted. Accordingly, in the resultant structure after dicing along the scribe lines, the dielectric material 150 covers side surfaces of the base substrate 101c, the FEOL structure 110c, and the front side BEOL structure 120c, and the dielectric material 250 covers side surfaces of the FEOL structure 210c, and the BEOL structure 220c as it is shown in FIG. 8.

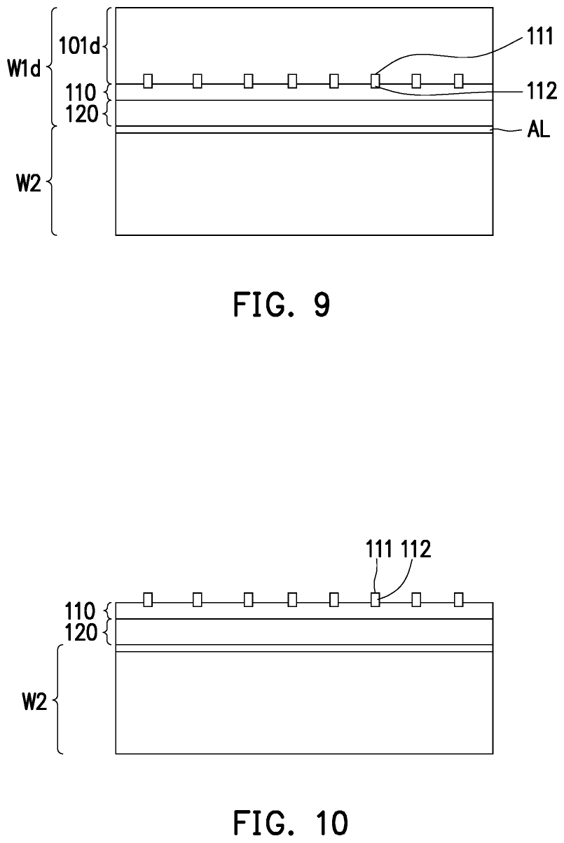

FIG. 9 to FIG. 12 illustrate cross sectional views of an intermediate stage in a manufacturing of an integrated circuit structure according to some exemplary embodiments of the present disclosure. It is noted that the manufacturing process of an integrated circuit structure 100d shown in FIG. 9 to FIG. 12 contains many features same as or similar to the manufacturing process of the integrated circuit structure 100 disclosed earlier with FIG. 1 to FIG. 5. For purpose of clarity and simplicity, detail description of same or similar features may be omitted, and the same or similar reference numbers denote the same or like components. The main differences between process and structure of the integrated circuit structure 100d shown in FIG. 9 to FIG. 12 and those of the integrated circuit structure 100 disclosed earlier with FIG. 1 to FIG. 5 are described as follows.

Referring to FIG. 9, in accordance with some embodiments of the disclosure, a semiconductor wafer W1′d is provided on a carrier W2. In some embodiments, the semiconductor wafer W1′d may include a base substrate 101′d, a FEOL structure 110 disposed on the base substrate 101′d, a front side BEOL structure 120 disposed over a front side of the FEOL structure 110. In some embodiments, the carrier W2 may be a carrier substrate, an integrated circuit, or an interposer. In the present embodiment, the carrier W2 is a carrier substrate, but the disclosure is not limited thereto. The semiconductor wafer W1′d is disposed on the carrier W2 with a bonding surface of the front side BEOL structure 120 bonded to the carrier W2 through an adhesive layer AL. The adhesive layer AL may be a high thermal conductive hybrid bonding layer, which may include diamond-like carbon (DLC) coating, silicon carbide coating, Cu-SiOx coating, SiON coating, or the like.

In accordance with some embodiments of the disclosure, the FEOL structure 110 (shown in an abstract form as a layer for convenience of illustration) may include a plurality of devices 112, a plurality of power/ground contacts 111 and a plurality of I/O contacts that are connecting the devices 112. In other words, the FEOL structure 110 may include various transistors (e.g. devices 112) and the associated contact regions, e.g. power/ground contacts 111, input/output (I/O) contacts, etc., required for such devices. The devices 112 may include various microelectronic devices, for example, a metal-oxide-semiconductor field (MOSFET) effect transistor, a large scale integration (LSI) system, an image sensor, such as a complementary metal-oxide-semiconductor (CMOS) imaging sensor (CIS), a micro-electro-mechanical system (MEMS), an active device, or a passive device. In some embodiments, the devices 112 are formed upon the top surface of the base substrate 101′d. In addition, the devices 112 may each be electrically separated from their neighboring individual devices by an interlayer insulating film. In one of the embodiments, the FEOL structure 110 may include a plurality of semiconductor device layers stacked monolithically.

In some exemplary embodiments, the FEOL structure 110 is formed at a base substrate 101′d. In some embodiments, the base substrate 101′d may be in a wafer form. In at least one embodiment, the base substrate 101′d may comprise silicon (Si). In some embodiments, the base substrate 101′d may include a semiconductor element, such as germanium (Ge), or a compound semiconductor, such as silicon carbide (SiC), gallium arsenide (GaAs), indium arsenide (InAs), or indium phosphide (InP). In some embodiments, the base substrate 101′d may be free of through substrate vias, but rather a bulk of semiconductor substrate.

Referring to FIG. 9 and FIG. 10, then, the base substrate 101′d is removed. The base substrate 101′d may be removed by a process similar to the thinning process for thinning the base substrate 101′ as it is described earlier. Such process is performed on a backside of the base substrate 101′d till the devices 112 on the FEOL structure 110 is exposed. In some embodiments, the process includes a grinding process. In some other embodiments, the process includes a chemical-mechanical polishing (CMP) process or the like. For example, the structure shown in FIG. 9 may be provided on a wafer grinding tool. Mechanical thinning may be used to remove the bulk of the wafer. After the mechanical thinning process is performed, a thin layer of silicon may still remain covering the devices 112. Then, a wet etching using tetramethylammonium hydroxide (TMAH) or potassium hydroxide (KOH) may further be applied. It is also favorable to use a proper brush cleaning or wet clean process, which may include wiping with isopropyl alcohol (IPA) followed by a water rinse and spin dry, to remove any trace of polish slurry which might act as an etch mask during the via exposure steps. In one or more embodiments, a blanket deep reactive ion etching (D-RIE) or a Si reactive ion etching (RIE) process may be performed to finally remove the base substrate 101′d and expose the devices 112. However, the method of removing the base substrate 101′d and exposing the devices 112 is not limited thereto.

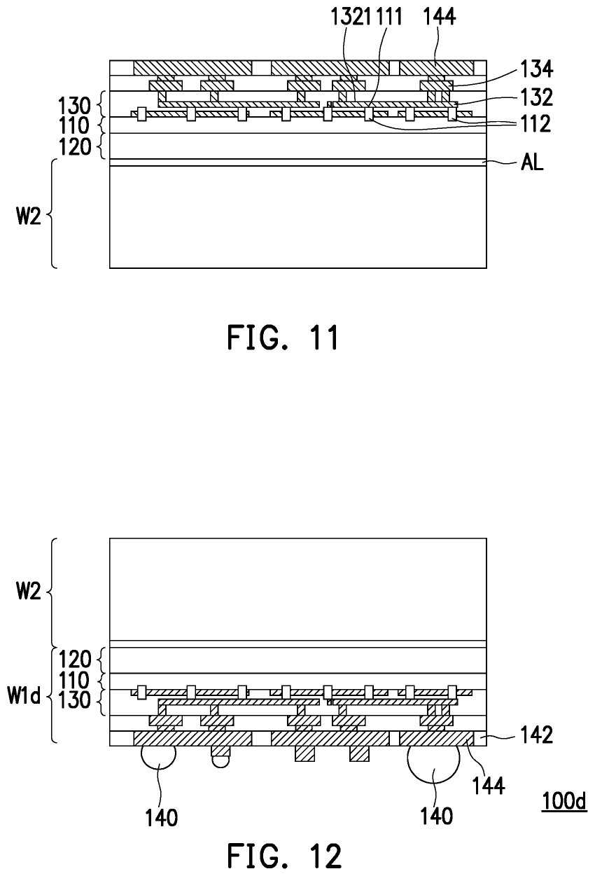

Referring to FIG. 11, then, the backside BEOL structure 130 is provided over the FEOL structure 110. In some embodiments, the backside BEOL structure 130 is directly provided on the FEOL structure 110 since the base substrate 101′d is removed. The backside BEOL structure 130 may include multiple layers of wirings 132 and dielectric passivation layers are built over a backside of the FEOL structure 110 that contains the devices 112. The backside BEOL structure 130 includes vias 134 and wirings 132 are fabricated atop the FEOL structure 110 as illustrated in FIG. 11. In some embodiments, the backside BEOL structure 130 may include at least one power/ground interconnect(s) 1321 connecting the power/ground contacts 111. As stated above, the wirings 132 (metallic structures) including the power/ground interconnect(s) 1321 for providing external interconnections (interconnects) are formed in many levels of Intra-Level Dielectric (ILD) layers for electrically connecting the power/ground contacts 111 on the FEOL structure 110 to external devices. That is to say, the layers of the backside BEOL structure 130 provide functions such as power and ground network (PDN) required for operating the circuitry in the integrated circuit structure 100d. In some embodiment, at least one passive device 134 may be integrated with metal and other materials in the backside BEOL structure 130. In some embodiments, the passive device 134 may include integrated passive dies (IPD), digitally tunable capacitors (DTC), metal-insulator-metal (MiM) decoupling capacitors, or the like.

With now reference to FIG. 12, at least one conductive bump(s) 140 is provided over a bonding surface of the backside BEOL structure 130. In some embodiments, the conductive bumps 140 are connected to the power/ground interconnects 1321 and may serve as power/ground terminals of the integrated circuit structure 100d. For example, a passivation layer 142 is applied atop the backside BEOL structure 130 and contact holes are opened and filled with a bonding metallurgy and the conductive bumps 140 are disposed onto selected locations on the bonding pads 144 as shown in FIG. 12. Accordingly, the conductive bumps 140 serve as the power/ground terminals of the integrated circuit structure 100d.

With such configuration, a part from those similar advantages discussed earlier in the previous embodiment, the base substrate 101′d of the integrated circuit structure 100d is removed, so the backside BEOL structure 130 is directly formed on the backside of the FEOL structure 110. Accordingly, an overall thickness of the integrated circuit structure 100d can be reduced.

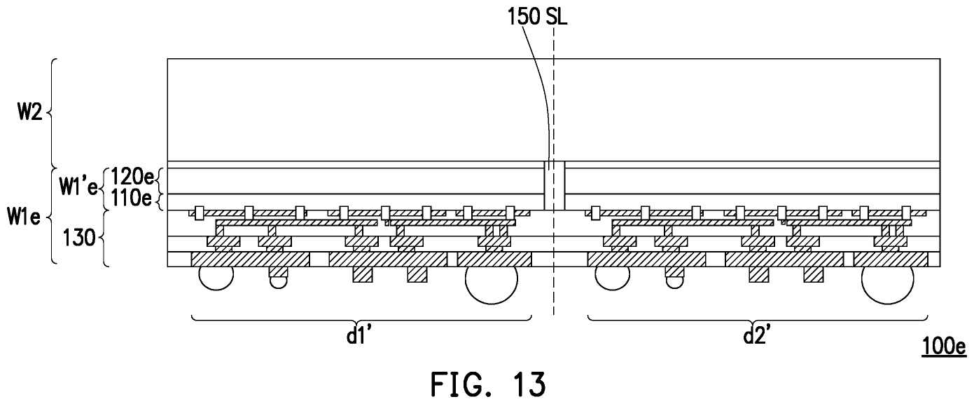

FIG. 13 illustrates a cross sectional view of an integrated circuit structure according to some exemplary embodiments of the present disclosure. It is noted that the integrated circuit structure 100e shown in FIG. 13 contains many features same as or similar to the integrated circuit structure 100a disclosed earlier with FIG. 6. For purpose of clarity and simplicity, detail description of same or similar features may be omitted, and the same or similar reference numbers denote the same or like components. The main differences between the integrated circuit structure 100e shown in FIG. 13 and the integrated circuit structure 100a disclosed earlier with FIG. 6 are described as follows.

With now reference to FIG. 13, in the present embodiment, the integrated circuit wafer W1e is a reconstructed wafer. That is, instead of providing the integral semiconductor wafer W1′d including the base substrate 101′d, the FEOL structure 110 and the front side BEOL structure 120 shown in FIG. 9, a plurality of semiconductor dies d1′, d2′ are firstly provided on the carrier W2. That is to say, the process in the embodiment shown in FIG. 9 to FIG. 12 is a wafer to wafer process while the process in the present embodiment is a die to wafer process. It is noted that two semiconductor dies d1′ and d2′ are shown in FIG. 13 merely for illustration purpose. More or less semiconductor dies may be provided on the carrier W2. Each of the semiconductor dies d1′/d2′ includes a FEOL structure 110e and a front side BEOL structure 120e. The layouts and the fabricating processes of the FEOL structure 110e and the front side BEOL structure 120e are similar to those of the FEOL structure 110a and the front side BEOL structure 120a described earlier regarding FIG. 6. In addition, the base substrate of the semiconductor dies d1/d2 is removed by the same process described above, so the backside BEOL structure 130 is directly formed on the backside of the FEOL structure 110e. Such semiconductor dies d1′, d2′ are joined together by, for example, a dielectric material 150 to form a reconstructed wafer W1′e. Then, the sequential processes (e.g. forming a backside BEOL structure 130) can be performed on the reconstructed wafer W1′e to form the integrated circuit structure 100e. In the resultant structure after dicing along the scribe line, the dielectric material 150 covers side surfaces of the FEOL structure 110e, and the front side BEOL structure 120e as it is shown in FIG. 13.

With such configuration, a part from those similar advantages discussed earlier in the previous embodiment, the semiconductor dies d1′, d2′ are provided on the carrier W2 independently, so electrical tests, or the like, can be firstly performed on the semiconductor dies d1′, d2′ before they are placed on the carrier W2. Such configuration ensures that only known good dies are incorporated into integrated circuit structure 100e, so as to improve yield rates of the integrated circuit structure 100e and reduce production cost.

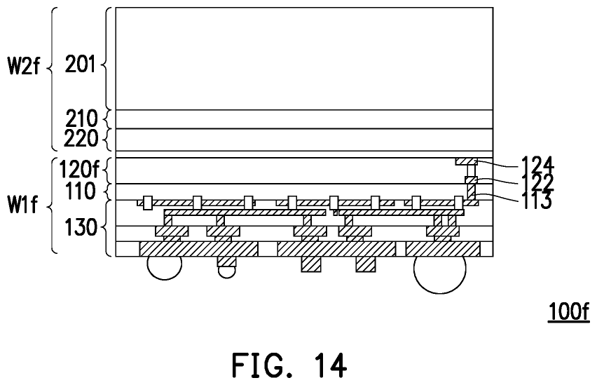

FIG. 14 illustrates a cross sectional view of an integrated circuit structure according to some exemplary embodiments of the present disclosure. It is noted that the integrated circuit structure 100f shown in FIG. 14 contains many features same as or similar to integrated circuit structure 100b disclosed earlier with FIG. 7. For purpose of clarity and simplicity, detail description of same or similar features may be omitted, and the same or similar reference numbers denote the same or like components. The main differences between the integrated circuit structure 100f shown in FIG. 14 and the integrated circuit structure 100b disclosed earlier with FIG. 7 are described as follows.

In the present embodiment, the carrier W2f may be another integrated circuit wafer, which is a semiconductor wafer with built-in integrated circuits. In such embodiment, for the integrated circuit wafer W1f, at least one I/O terminal 124 is disposed on a bonding surface of the front side BEOL structure 120f and (electrically) connected to the I/O contact 113 on the FEOL structure 110. More or less of the I/O terminal 124 can be provided and is configured for electrically connecting the numerous active devices on the FEOL structure 110 to external devices (e.g. carrier W2f). In some embodiments, the I/O terminal 124 may be connected to the I/O interconnect 122 and the I/O contact 113 through interconnect vias, or any other forms of interconnects. The layouts and the fabricating processes of the FEOL structure 110 and the front side BEOL structure 120f in the present embodiment are similar to those of the FEOL structure 110 and the front side BEOL structure 120b described earlier regarding FIG. 7. In addition, the base substrate of the integrated circuit wafer w1f is removed to further reduce the thickness, so the backside BEOL structure 130 is directly formed on the backside of the FEOL structure 110.

Accordingly, the carrier W2f may include a base substrate 201, a FEOL structure 210 and a front side BEOL structure 220 (each of which is shown in an abstract form as a layer for convenience of illustration). In the present embodiment, the I/O terminals of the carrier W2f are disposed on a bonding surface of the carrier W2f. Therefore, when a wafer to wafer bonding (face to face bonding) process is performed, the I/O terminals 124 on the front side BEOL structure 120f of the integrated circuit wafer W1f are bonded to the I/O terminals on the front side BEOL structure 220 of the carrier W2f for signal communication. Alternatively, the I/O terminals from front side BEOL structure of the integrated circuit wafer W1f are directly bonded to I/O terminals from the front side BEOL structure of the W2f through an AL layer (not labeled), which contains bonded metal pads and dielectrics.

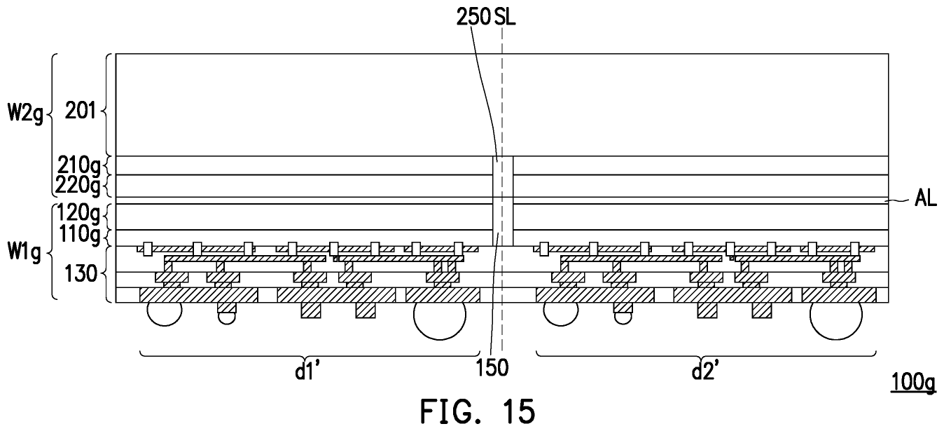

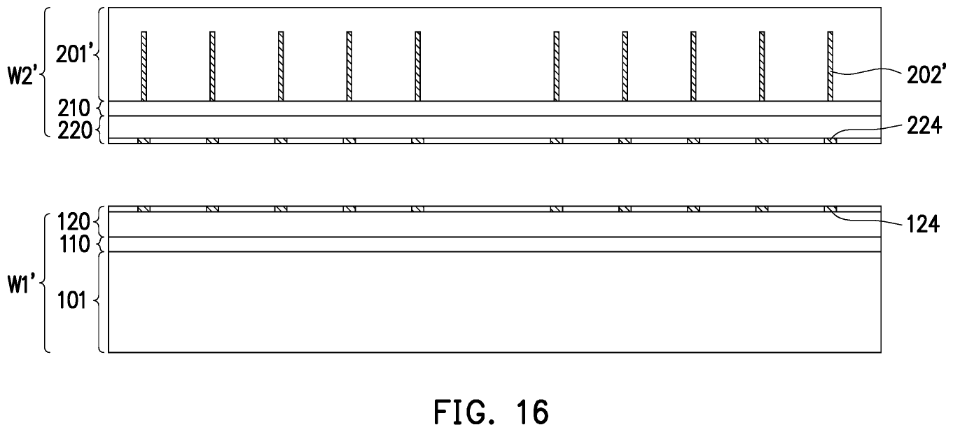

FIG. 15 illustrates a cross sectional view of an integrated circuit structure according to some exemplary embodiments of the present disclosure. It is noted that the integrated circuit structure 100g shown in FIG. 15 contains many features same as or similar to the integrated circuit structure 100c disclosed earlier with FIG. 8. For purpose of clarity and simplicity, detail description of same or similar features may be omitted, and the same or similar reference numbers denote the same or like components. The main differences between the integrated circuit structure 100g shown in FIG. 15 and the integrated circuit structure 100c disclosed earlier with FIG. 8 are described as follows.

In the present embodiment, the integrated circuit wafer W1g is a reconstructed wafer. That is, a plurality of semiconductor dies d1′, d2′ are provided on the carrier W2g and joined together by, for example, a dielectric material 150 to form the reconstructed wafer W1g. In the present embodiment, the carrier W2g may also be a reconstructed wafer, which includes a plurality of FEOL structures 210g separated from one another and a plurality of BEOL structures 220g separated from one another and stacked on the FEOL structures 210g respectively. Stacks of the FEOL structures 210g and the BEOL structures 220g are joined together by, for example, a dielectric material 250 to form the reconstructed wafer W2g. Each of the semiconductor dies d1′/d2′ includes a FEOL structure 110g, a front side BEOL structure 120g and a backside BEOL structure 130 without the base substrate. The layouts and the fabricating processes of the semiconductor dies d1′/d2′ are similar to those of the semiconductor dies d1/d2 described earlier in FIG. 8. In addition, the base substrate of the integrated circuit wafer W1g is removed to further reduce the thickness, so the backside BEOL structure 130 is directly formed on the backside of the FEOL structure 110g of the semiconductor dies d1′/d2′. Accordingly, in the resultant structure after dicing along the scribe lines SL, the dielectric material 150 covers side surfaces of the the FEOL structure 110g, and the front side BEOL structure 120g, and the dielectric material 250 covers side surfaces of the FEOL structure 210g, and the BEOL structure 220g as it is shown in FIG. 15.

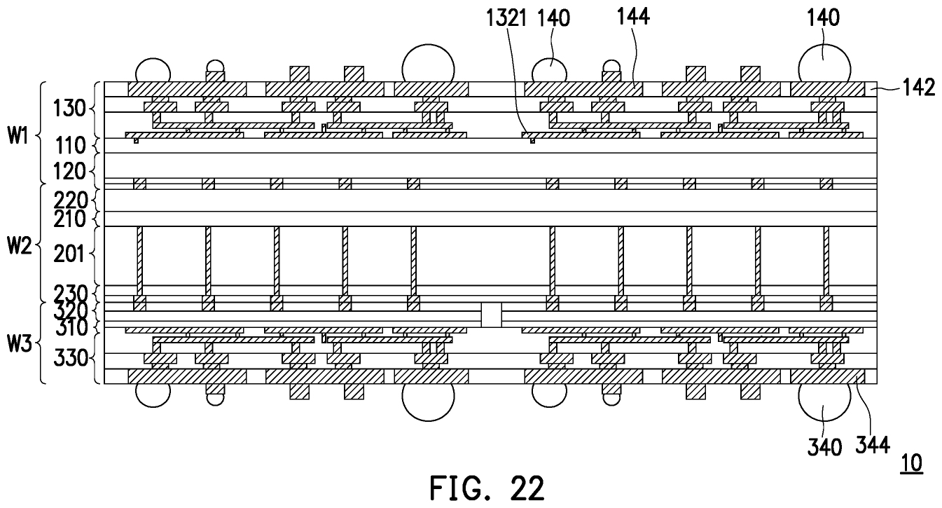

FIG. 16 to FIG. 22 illustrate cross sectional views of an intermediate stage in a manufacturing of a stacked integrated circuit structure according to some exemplary embodiments of the present disclosure. The structure and the process of the integrated circuit structures described in the previous embodiments may be applied to a stacked integrated circuit structure 10 shown in FIG. 22. In other words, the carrier where the integrated circuit structure is disposed may also be an integrated circuit structure. Accordingly, the manufacturing process of a stacked integrated circuit structure 10 shown in FIG. 16 to FIG. 22 contains many features same as or similar to the manufacturing process of the integrated circuit structure 100 disclosed earlier with FIG. 1 to FIG. 5. For purpose of clarity and simplicity, detail description of same or similar features may be omitted, and the same or similar reference numbers denote the same or like components.

Referring to FIG. 16, in accordance with some embodiments of the disclosure, a first integrated circuit W1′ and a semiconductor device W2′ are provided. In the present embodiment, the first integrated circuit W1′ and the semiconductor device W2′ may each be in a wafer form. In some embodiments, the first integrated circuit W1′ includes a first base substrate 101, a first FEOL structure 110 disposed on the first base substrate 101, a first front side BEOL structure 120 disposed on a front side of the first FEOL structure 110. In some embodiments, the first FEOL structure 110 (shown in an abstract form as a layer for convenience of illustration) may be similar to the FEOL structure 110 shown in FIG. 1, which includes at least one first device and at least one first power/ground contact connecting the first device. In some exemplary embodiments, the first FEOL structure 110 is formed at the base substrate 101 and interconnected on top and bottom using the front side BEOL structure 120 and the backside BEOL structure (which will be formed subsequently) respectively. In some embodiments, the first base substrate 101 may be in a wafer form. In at least one embodiment, the first base substrate 101 may include a semiconductor element, such as silicon (Si), germanium (Ge), or a compound semiconductor, such as silicon carbide (SiC), gallium arsenide (GaAs), indium arsenide (InAs), or indium phosphide (InP).

In some embodiments, the first FEOL structure 110 may include a plurality of first devices and an interlayer insulating layer. The first devices may include various microelectronic devices, for example, a metal-oxide-semiconductor field (MOSFET) effect transistor, a large scale integration (LSI) system, an image sensor, such as a complementary metal-oxide-semiconductor (CMOS) imaging sensor (CIS), a micro-electro-mechanical system (MEMS), an active device, or a passive device. In addition, the devices may each be electrically separated from their neighboring individual devices by the interlayer insulating film. In one of the embodiments, the first FEOL structure 110 may include a plurality of semiconductor device layers stacked monolithically. In some embodiments, the first FEOL structure 110 may include various transistors (e.g. devices) and the associated contact regions, e.g. power/ground contacts, input/output (I/O) contacts, etc., required for such devices. In some embodiments, interconnect vias for connecting the device contacts (e.g., I/O contacts) to the first front side BEOL structure 120 and surrounded by the interlayer insulating layer is also presented in the first FEOL structure 110.

In accordance with some embodiments of the disclosure, the first FEOL structure 110 may include a plurality of first power/ground contacts and a plurality of first I/O contacts. In the present embodiment, a first I/O terminal 124 is disposed on a bonding surface of the first front side BEOL structure 120 and connected to the first I/O contacts of the first FEOL structure 110 through interconnect vias or any forms of interconnects.

In some embodiments, the semiconductor device W2′ may be an I/O chip, an active interposer, or the like. In general, the interposer serves as the high density and high bandwidth interconnections between the chips on the interposers. For an active interposer, passive devices and active circuits are integrated together to enhance the signal integrity, and power integrity, and to lower power consumptions. The actives circuits in the active interposer may include equalizer, clock distribution network, as well as DC-DC converter circuit. Also, wireless power delivery network may be included to reduce the number and space of power/ground terminals (balls) and vias. In some embodiments, the semiconductor device W2′ may include a base substrate 201′, an intermediate FEOL structure 210, and an intermediate front side BEOL structure 220. In some embodiments, the intermediate front side BEOL structure 220 may include at least one front side I/O terminal(s) 224 corresponding to the first I/O terminals 124 of the first integrated circuit W1′. In some embodiments, the intermediate base substrate 201′ may include at least one blind via 202′ (a plurality of blind vias 202′ are illustrated but not limited thereto) extended from the intermediate FEOL structure 210 and electrically connected to the front side I/O terminals 224.

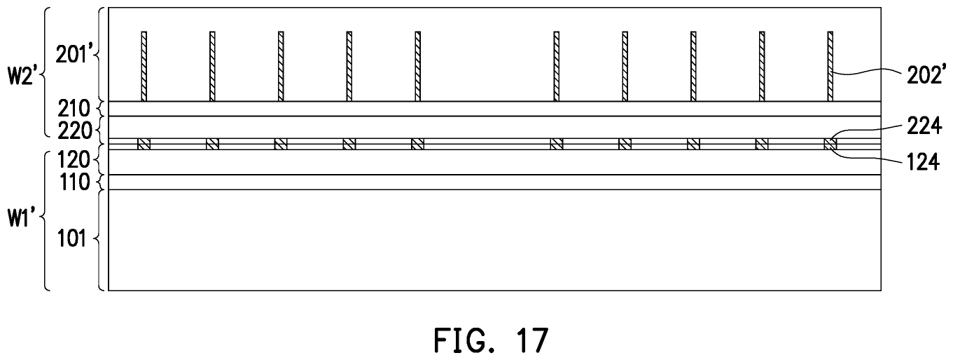

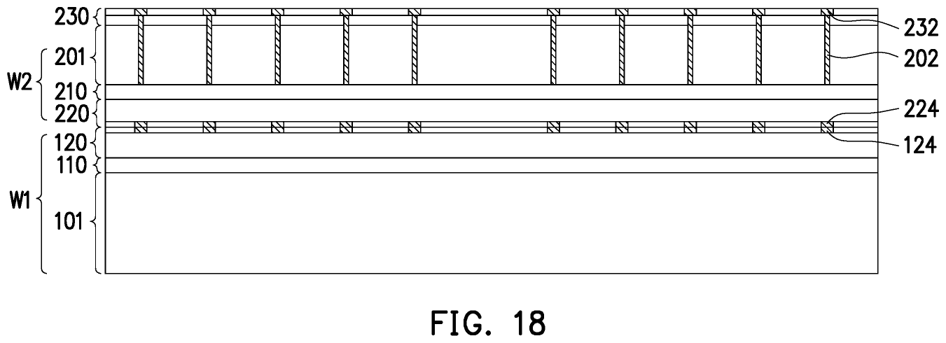

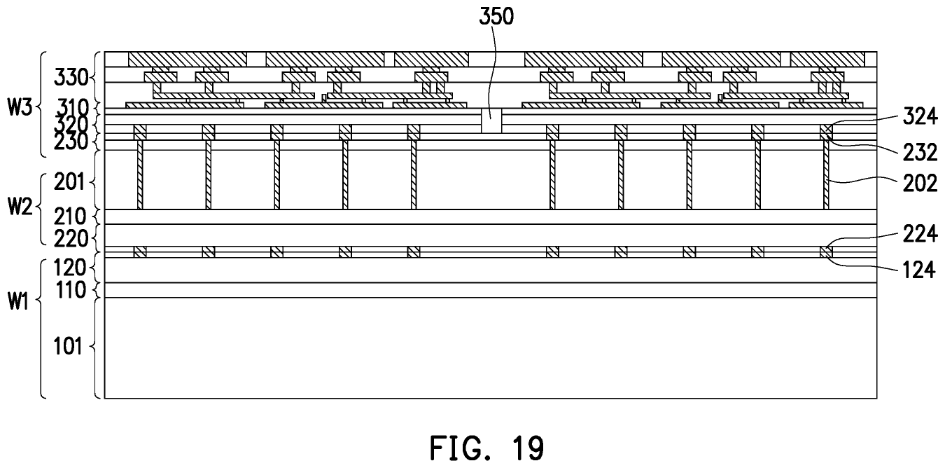

With now reference to FIG. 17, the first integrated circuit W1′ are bonded with the semiconductor device W2′ by wafer to wafer bonding process. For example, metal-to-metal thermal compression bonding, or other type of hybrid bonding technique may be applied. After the bonding process, the front side I/O terminals 224 of the semiconductor device W2′ are connected to the first I/O terminals 124 of the first integrated circuit W1′ respectively.

With now reference to FIG. 18, a thinning process is performed on the intermediate base substrate 201′ to form the through vias 202 extending through the intermediate base substrate 201. The process of forming through vias 202 start with the blind vias 202′ as it is shown in FIG. 16, and eventually exposed such that the metal is substantially coplanar with the back surface of the base substrate 201 as it is shown in FIG. 18. a thinning process is performed on a backside of the base substrate 101′ till an end of the blind via 102′ is exposed, so as to form the through substrate vias 102 shown in FIG. 2. In some embodiments, the thinning process includes a grinding process. In some other embodiments, the thinning process includes a chemical-mechanical polishing (CMP) process or the like. Then, an intermediate backside BEOL structure 230 is formed on the back side of the intermediate base substrate 201. In some embodiments, the intermediate backside BEOL structure 230 may include a plurality of backside I/O terminals 232 electrically connected to the through vias 202. At this point, the fabrication of semiconductor device W2 is substantially completed.

For the structural point of view, the semiconductor device W2 includes the (intermediate) base substrate 201, a plurality of intermediate I/O terminals 232 and 224 disposed on two opposite sides of the base substrate 201, and at least one (intermediate) through via 202 extending through the base substrate 201. In some embodiments, the intermediate I/O terminals 232 and 224 includes a plurality of backside I/O terminals 232 disposed at a backside of the base substrate 201, and a plurality of front side I/O terminals 224 disposed at a front side of the base substrate 201. In some embodiments, I/O terminals 232 and 224 of the semiconductor device W2 may serves as I/O interconnections between the integrated circuits (e.g., integrated circuits W1 and W3) that are bonded to the semiconductor device W2.

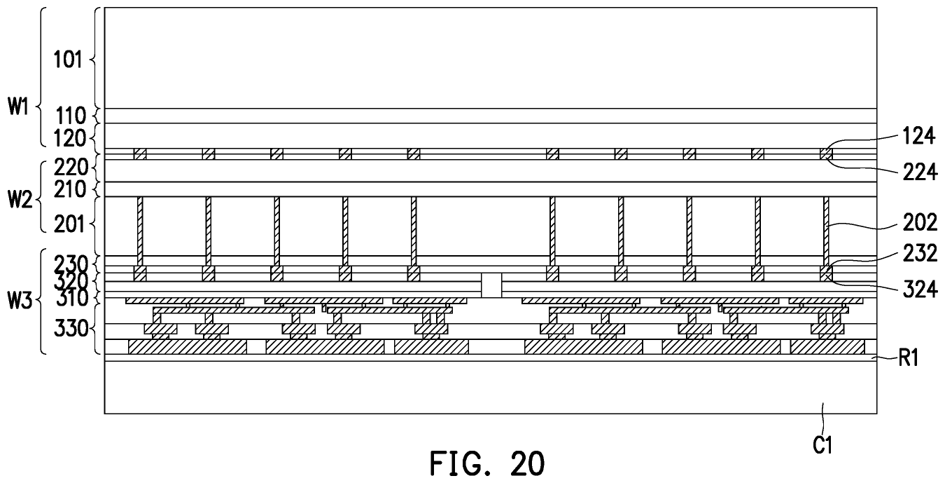

With now reference to FIG. 19, in some embodiments, a second integrated circuit W3 is stacked over the first integrated circuit W1′ and bonded with the power/ground terminals 124 of the first front side BEOL structure 120 through the semiconductor device W2. In some embodiments, the I/O terminals 232 of the semiconductor device W2 are connected to at least one second I/O terminal 324 of the second integrated circuit W3, and the I/O terminals 224 of the semiconductor device W2 are connected to at least one first I/O terminal 124 of the first integrated circuit W1. In some embodiments, the second integrated circuit W3 may be a core chip (logic wafer), but the disclosure is not limited thereto. The structural configuration of the second integrated circuit W3 may be similar to that of the integrated circuit wafer W1g overlaying the carrier W2g shown in FIG. 15. However, other suitable integrated circuit structure may be applied to the present embodiments. The elements in the second integrated circuit W3 may be found referring to the like elements in the integrated circuit structure 100g in FIG. 15. For example, with the like elements in f integrated circuit structure 100g starting with number “1,” the elements correspond to the elements in the second integrated circuit W3 and having reference numerals starting with number “3.” For example, in the illustrated FIG. 19, the second integrated circuit W3 may include a second FEOL structure 310, a second front side BEOL structure 320, and a second backside BEOL structure 330. For purpose of clarity and simplicity, detail description of same or similar features may be omitted, and the same or similar reference numbers denote the same or like components.

In detail, the second FEOL structure 310 (shown in an abstract form as a layer for convenience of illustration) includes at least one second device and at least one second power/ground contact connecting the second device. The second front side BEOL structure 320 is disposed on a front side of the second front side BEOL structure 310. The second backside BEOL structure 330 is disposed on a backside of the second FEOL structure 310, which is where the second power/ground contact disposed. The second backside BEOL structure 330 includes second power/ground interconnect(s) connecting the second power/ground contacts of the second devices. In the present embodiment, second integrated circuit W3 is bonded to the semiconductor device W2 through a die to wafer bonding. Namely, a dielectric material 350 is filled between die units to form a reconstructed wafer, and the second backside BEOL structure 330 is then formed on the reconstructed wafer. Therefore, after dicing process, the dielectric material 350 would cover side surfaces of the second FEOL structure 310 and the second front side BEOL structure 320. However, the disclosure does not limited the forms of the second integrated circuit W3.

With now reference to FIG. 20, then, the resultant structure of FIG. 19 is flipped over and bonded to a package carrier C1. In some embodiments, the package carrier C1 may be a glass carrier, a ceramic carrier, or the like. The package carrier C1 may have a round top-view shape and may be a size of a silicon wafer. In some embodiments, a release layer RL may be provided on the package carrier C1. In some embodiments, the release layer RL may be removed along with package carrier C1 from the overlying structures that will be formed in subsequent steps. The release layer RL may include an adhesive or a glue material. In some embodiments, the release layer RL may be dispensed as a liquid and cured. In other embodiments, the release layer RL may be formed by lamination. In some embodiments, the release layer RL is photosensitive and is easily detached from package carrier C1 by irradiating with ultra-violet (UV) light or laser. For example, the release layer RL may include a light-to-heat-conversion (LTHC) coating. In some other embodiments, the release layer RL 106 includes heat-sensitive adhesive.

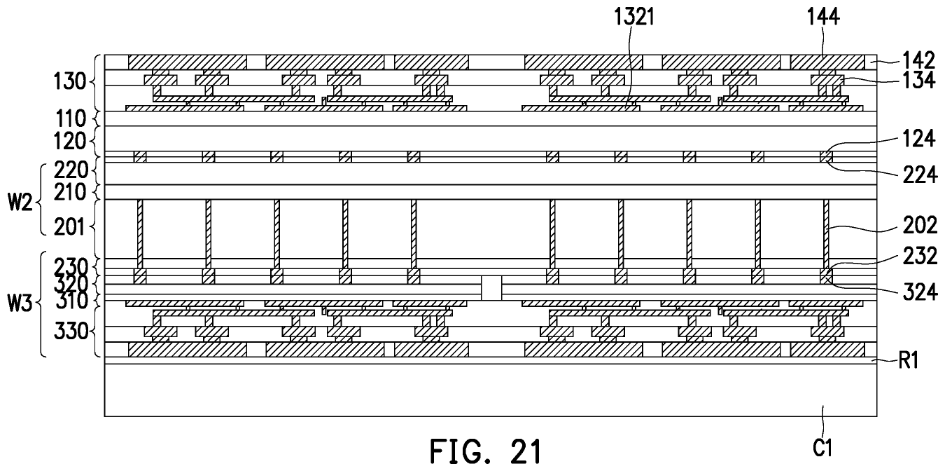

With now reference to FIG. 21, then, processes that are similar to the process shown in FIG. 9 to FIG. 11 are applied to the first integrated circuit W1′. Namely, the first base substrate 101 is removed, and a first backside BEOL structure 130 is then formed on the first FEOL structure 110. In some embodiments, the first backside BEOL structure 130 may include multiple layers of wirings, vias and dielectric passivation layers are built over a backside of the first FEOL structure 110 that contains the first devices 112. In some embodiments, the first backside BEOL structure 130 may include at least one power/ground interconnect(s) 1321 connecting the power/ground contacts of the first FEOL structure 110. As stated above, the wirings 132 (metallic structures) including the power/ground interconnect(s) 1321 for providing external interconnections (interconnects) are formed in many levels of Intra-Level Dielectric (ILD) layers for electrically connecting the power/ground contacts 111 on the FEOL structure 110 to external devices. That is to say, the layers of the backside BEOL structure 130 provide functions such as power and ground network (PDN) required for operating the circuitry in the integrated circuit structure W1. In some embodiment, at least one passive device 134 may be integrated with metal and other materials in the first backside BEOL structure 130. In some embodiments, the passive device 134 may include integrated passive dies (IPD), digitally tunable capacitors (DTC), metal-insulator-metal (MiM) decoupling capacitors, or the like.

With now reference to FIG. 22, then, at least one first conductive bump(s) 140 is provided on the bonding pads 144 of the first backside BEOL structure 130. In some embodiments, the first conductive bumps 140 are connected to the power/ground interconnects 1321 and may serve as power/ground terminals of the integrated circuit structure W1. For example, a passivation layer 142 is applied atop the first backside BEOL structure 130 and contact holes are opened and filled with a bonding metallurgy and the first conductive bumps 140 are disposed onto selected locations on bonding pads 144 as shown in FIG. 22. Accordingly, the first conductive bumps 140 serve as the power/ground terminals of the first integrated circuit W1. In at least one of the embodiments, the integrated circuit structure W1 may be a power management integrated circuit (PMIC), so the first conductive bumps 140 may be configured to electrically connect numerous active devices of the first FEOL structure 110 to external devices such as a power source, a substrate, an interposer, a printed circuit board, or the like. At this point, the manufacturing process of first integrated circuit W1 is substantially completed.

Then, the package carrier C1 is removed to exposed bond pads 344, at least one second conductive bump(s) 340 is provided on the bond pads 344 of the second backside BEOL structure 330. In some embodiments, the second conductive bumps 340 are connected to the power/ground interconnects of the second backside BEOL structure 330 and may serve as power/ground terminals of the integrated circuit structure W3. In one of the embodiments, the second backside BEOL structure 330 may further include I/O interconnects for connecting I/O contacts of the second FEOL structure 310. At least one of the conductive bumps 340 may be connected to the I/O interconnects and serve as the I/O terminal of the second integrated circuit W3. The disclosure does not limit the arrangements of I/O terminals. At this point, the manufacturing process of stacked integrated circuit structure 10 is substantially completed, and the second integrated circuit W3 is stacked over (or under, depending on the orientation of the product) the first integrated circuit W1 and bonded with the first front side BEOL structure 110 of the first integrated circuit W1 through the semiconductor device W2.

FIG. 23 illustrates a cross sectional view of a stacked integrated circuit structure according to some exemplary embodiments of the present disclosure. It is noted that the stacked integrated circuit 10a shown in FIG. 23 contains many features same as or similar to the stacked integrated circuit 10 disclosed earlier with FIG. 16 to FIG. 22. For purpose of clarity and simplicity, detail description of same or similar features may be omitted, and the same or similar reference numbers denote the same or like components. The main differences between the integrated circuit structure 100e shown in FIG. 13 and the integrated circuit structure 100a disclosed earlier with FIG. 6 are described as follows.

In some embodiments, the manufacturing process of the first integrated circuit W1a may start out from a reconstructed wafer. That is, a plurality of semiconductor dies d1, d2 are provided on the second integrated circuit W3a and joined together by, for example, a dielectric material 150 to form the reconstructed wafer W1a. Then, the first backside BEOL structure is formed over the reconstructed wafer. Accordingly, after the dicing process, for the final structure of the stacked integrated circuit 10a, the dielectric material 150 covers side surfaces of the first FEOL structure 110a, and the first front side BEOL structure 120a.

In some embodiments, for high performance applications, the second FEOL structure 310 may be built on a silicon-on-insulator (SOI) wafer or other similar substrate in which an embedded layer (e.g., a buried oxide (BOX) layer 303) may be implemented under the second FEOL structure 310 (e.g., device region). Accordingly, the second integrated circuit W3a includes a second base substrate 301a, a second FEOL structure 310, and a second BEOL structure 320. In the present embodiment, the second base substrate 301a is an SOI wafer includes a buried oxide (BOX) layer 303 disposed on a bulk silicon body. In general, active silicon device channels are patterned on top of the BOX layer 323 and are isolated from other device channels by shallow trench isolation (STI) regions typically including insulators such as silicon nitride and silicon oxide. The second FEOL structure 310 is disposed over the second base substrate 301a and the second FEOL structure 310 is disposed over and electrically connecting the second FEOL structure 310, wherein the second BEOL structure 320 is bonded with the first front side BEOL structure 120a.

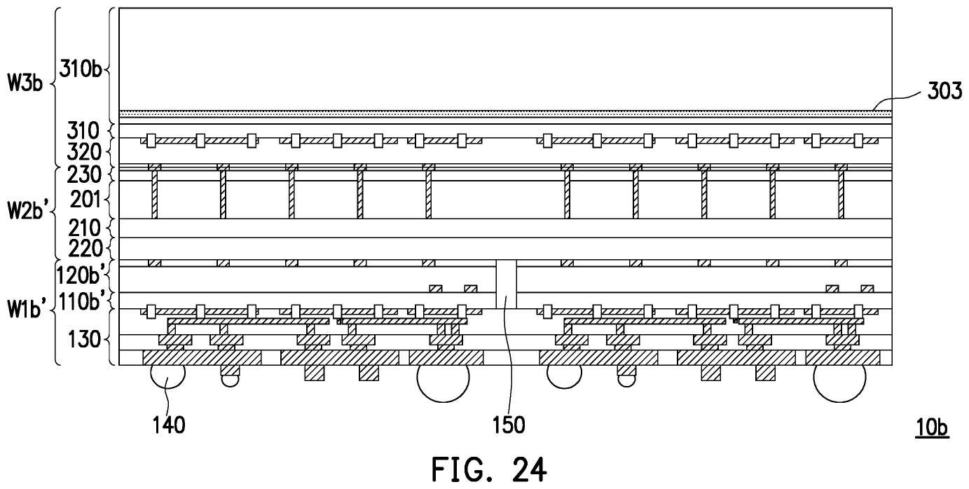

FIG. 24 illustrates a cross sectional view of a stacked integrated circuit structure according to some exemplary embodiments of the present disclosure. It is noted that the stacked integrated circuit 10b shown in FIG. 24 contains many features same as or similar to the stacked integrated circuit 10 disclosed earlier with FIG. 16 to FIG. 22. For purpose of clarity and simplicity, detail description of same or similar features may be omitted, and the same or similar reference numbers denote the same or like components. The main differences between the stacked integrated circuit 10b shown in FIG. 24 and the integrated circuit structure 100a disclosed earlier with FIG. 6 are described as follows.

Referring to FIG. 24, in accordance with some embodiments of the disclosure, the stacked integrated circuit 10b includes a first integrated circuit W1b′, a second integrated circuit W3b stacked over and bonded to the first integrated circuit W1b′ through a semiconductor device W2b′. In the present embodiments, the first integrated circuit W1b′ is bonded to the semiconductor device W2b′ by a die to wafer bonding process. Namely, a dielectric material 150 is filled between die units (each including first FEOL structure 110b′ and first front side BEOL structure 120b′) to form a reconstructed wafer, and the second backside BEOL structure 130 is then formed on such reconstructed wafer. Therefore, after dicing process, the dielectric material 150 would cover side surfaces of the first FEOL structure 110b′ and the first front side BEOL structure 120b′. However, the disclosure does not limited the forms of the first integrated circuit W1b′.

In the present embodiment, for high performance applications, the second FEOL structure 310 may be built on a silicon-on-insulator (SOI) wafer or other similar substrate in which an embedded layer (e.g., a buried oxide (BOX) layer 303) may be implemented under the second FEOL structure 310 (e.g., device region). Accordingly, the second integrated circuit W3b includes a second base substrate 301b, a second FEOL structure 310, and a second BEOL structure 320. In the present embodiment, the second base substrate 301b is an SOI wafer includes a buried oxide (BOX) layer 303 disposed on a bulk silicon body. In general, active silicon device channels are patterned on top of the BOX layer 323 and are isolated from other device channels by shallow trench isolation (STI) regions typically including insulators such as silicon nitride and silicon oxide. The second FEOL structure 310 is disposed over the second base substrate 301b and the second FEOL structure 310 is disposed over and electrically connecting the second FEOL structure 310. In some embodiments, the second BEOL structure 320 of the second integrated circuit W3b is bonded with the first front side BEOL structure 120b′ of the first integrated circuit W1b′ through the semiconductor device W2b′.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, an integrated circuit structure includes a front end of line structure, a front side back end of line structure, and a backside back end of line structure. The front end of line structure includes a device and a power/ground and/or I/O contact connecting the device. The front side back end of line structure disposed over a front side of the front end of line structure. The backside back end of line structure is disposed over a backside of the FEOL structure and includes a power/ground interconnect connecting the power/ground contact.

In accordance with some embodiments of the disclosure, a stacked integrated circuit structure includes a first integrated circuit and a second integrated circuit stacked over the first integrated circuit and bonded with the first front side BEOL structure. The first integrated circuit includes a first FEOL structure, a first front side BEOL structure, and a first backside BEOL structure. The first FEOL structure includes a first device and a first power/ground contact connecting the first device. The first front side BEOL structure is disposed over a front side of the first FEOL structure. The first backside BEOL structure is disposed on a backside of the first FEOL structure and includes a first power/ground interconnect connecting the first power/ground contact.

In accordance with some embodiments of the disclosure, a method of manufacturing an integrated circuit structure includes the following steps. A semiconductor wafer is provided on a carrier, wherein the semiconductor wafer includes a base substrate, a FEOL structure on the base substrate and having a device and a power/ground contact connecting the device, and a front side BEOL structure on the FEOL structure and bonded with the carrier. A backside BEOL structure is provided over the semiconductor wafer, wherein the backside BEOL structure includes a power/ground interconnect connecting power/ground contact. A conductive bump is provided over the backside BEOL structure, wherein the conductive bump connects the power/ground interconnect.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit structure, comprising:
a front end of line (FEOL) structure comprising a device and a power/ground contact connecting the device;
a front side back end of line (BEOL) structure disposed over a front side of the FEOL structure;
a backside BEOL structure disposed over a back side of the FEOL structure and comprising a power/ground interconnect connecting the power/ground contact; and
a carrier disposed on a bonding surface of the front side BEOL structure.

2. The integrated circuit structure as claimed in claim 1, wherein the front side BEOL structure is free of power/ground interconnect connecting the power/ground contact.

3. The integrated circuit structure as claimed in claim 1, further comprising a base substrate disposed between the FEOL structure and the backside BEOL structure and a through substrate via extending through the base substrate and connecting the power/ground contact.

4. The integrated circuit structure as claimed in claim 1, further comprising a power/ground terminal disposed on the backside BEOL structure and connecting the power/ground interconnect.

5. The integrated circuit structure as claimed in claim 1, further comprising an I/O terminal disposed on a bonding surface of the front side BEOL structure and connecting an I/O contact on the FEOL structure.

6. The integrated circuit structure as claimed in claim 1, wherein the carrier comprises a carrier substrate, an integrated circuit, a semiconductor wafer, or an interposer.

7. The integrated circuit structure as claimed in claim 1, further comprising an I/O terminal disposed on a bonding surface of the backside BEOL structure and connecting an I/O contact on the FEOL structure.

8. The integrated circuit structure as claimed in claim 1, further comprising a dielectric material covering side surfaces of the FEOL structure, and the front side BEOL structure.

9. A stacked integrated circuit structure, comprising:
a first integrated circuit comprising:
a first FEOL structure comprising a first device and a first power/ground contact connecting the first device;
a first front side BEOL structure disposed over a front side of the first FEOL structure; and
a first backside BEOL structure disposed on a backside of the first FEOL structure and comprising a first power/ground interconnect connecting the first power/ground contact; and
a second integrated circuit stacked over the first integrated circuit and bonded with the first front side BEOL structure.

10. The stacked integrated circuit structure as claimed in claim 9, wherein the first integrated circuit further comprises a dielectric material covering side surfaces of the first FEOL structure, and the first front side BEOL structure.

11. The stacked integrated circuit structure as claimed in claim 9, wherein the first integrated circuit further comprises a first I/O terminal on a bonding surface of the first front side BEOL structure bonded with second integrated circuit.

12. The stacked integrated circuit structure as claimed in claim 9, wherein the second integrated circuit comprises:
a second FEOL structure comprising a second device and a second power/ground contact connecting the second device;
a second front side BEOL structure disposed on a front side of the first front side BEOL structure; and
a second backside BEOL structure disposed on a backside of the first front side BEOL structure where the second power/ground contact disposed.

13. The stacked integrated circuit structure as claimed in claim 9, wherein the second integrated circuit comprises:
a second base substrate;
a second FEOL structure disposed over the second base substrate; and
a second BEOL structure disposed over and electrically connecting the second FEOL structure, wherein the second BEOL structure is bonded with the first front side BEOL structure.

14. The stacked integrated circuit structure as claimed in claim 13, wherein second base substrate comprises a SOI wafer with a buried oxide (BOX) layer.

15. The stacked integrated circuit structure as claimed in claim 9, further comprising a semiconductor device disposed between the first integrated circuit and the second integrated circuit.

16. The stacked integrated circuit structure as claimed in claim 5, wherein the semiconductor device comprises:
an intermediate base substrate;
a plurality of intermediate I/O terminals on two opposite sides of the intermediate substrate; and
an intermediate through via extending through the intermediate base substrate and connecting the plurality of intermediate I/O terminals, wherein the plurality of intermediate I/O terminals are connected to a first I/O terminals of the first integrated circuit and a second I/O terminals of the second integrated circuit respectively.

17. A method of manufacturing an integrated circuit structure, comprising:
providing a semiconductor wafer on a carrier, wherein the semiconductor wafer comprising a base substrate, a FEOL structure on the base substrate and having a device and a power/ground contact connecting the device, and a front side BEOL structure on the FEOL structure and bonded with the carrier;
providing a backside BEOL structure over the semiconductor wafer, wherein the backside BEOL structure comprising a power/ground interconnect connecting power/ground contact; and
providing a conductive bump over the backside BEOL structure, wherein the conductive bump connects the power/ground interconnect.

18. The method of manufacturing an integrated circuit structure as claimed in claim 17, wherein the base substrate comprises a through via extending through the base substrate and connecting the power/ground contact and the backside BEOL structure.

19. The method of manufacturing an integrated circuit structure as claimed in claim 18, wherein the method of forming the through via comprises:
providing a blind via on the base substrate for connecting the power/ground contact; and
performing a thinning process on a backside of the base substrate till an end of the blind via is exposed.

20. The method of manufacturing an integrated circuit structure as claimed in claim 17, further comprising:
removing the base substrate, wherein the backside BEOL structure is provided over the FEOL structure.
